(19) United States
(12) Patent Application Publication
(10) Pub. No.: US 2003/0020137 A1
(43) Pub. Date: Jan. 30, 2003

(54) Structure and method for fabricating semiconductor inductor and balun structures utilizing the formation of a compliant substrate

(75) Inventors: Bruce Allen Bosco, Phoenix, AZ (US); Rudy M. Emrick, Gilbert, AZ (US); Steven James Franson, Scottsdale, AZ (US); Nestor Javier Escalera, Gilbert, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTORLA, INC., Schaumburg, IL

(21) Appl. No.: 09/911,542

(22) Filed: Jul. 25, 2001

(51) Int. Cl. H01L 29/04

(52) U.S. Cl. 257/531; 257/64; 257/69; 257/51

(57) ABSTRACT

Various semiconductor device structures that include an inductor or balun can be formed using a semiconductor structure having a monocrystalline silicon substrate, an amorphous oxide material overlying the monocrystalline silicon substrate, a monocrystalline perovskite oxide material overlying the amorphous oxide material; and a monocrystalline compound semiconductor material overlying the monocrystalline perovskite oxide material, and/or other types of material such as metals and non-metals.

### FIELD OF THE INVENTION

This invention relates generally to semiconductor structures and devices and to a method for their fabrication, and more specifically to inductors and baluns formed in semiconductor structures having a monocrystalline material layer comprised of semiconductor material, compound semiconductor material, and/or other types of material such as metals and non-metals.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

A significant disadvantage of inductors and baluns formed using conventional semiconductor structures is that they occupy a relatively large amount of area on the active surface of the die because they are typically formed entirely in the X-Y plane on the surface of the die. A reduction in surface area occupied by the device would provide a number of advantages. For example, a reduction in surface area requirements can reduce microchip fabrication costs. Thus, there is a significant need for inductor and balun structures that occupy less die surface area through use of multilayered semiconductor structures. The present invention provides these and other advantageous results.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIGS. 21-23 illustrate schematically, in cross section, the formation of a yet another embodiment of a device structure in accordance with the invention;

FIGS. 24 and 25 illustrate schematically, in cross section, device structures that can be used in accordance with various embodiments of the invention;

FIGS. 26-30 include illustrations of cross-sectional views of a portion of an integrated circuit that includes a compound semiconductor portion, a bipolar portion, and an MOS portion in accordance with what is shown herein;

FIG. 31 illustrates schematically, in cross-section, a semiconductor device structure that includes a multilayered inductor formed under a silicon substrate layer and on a compound semiconductor layer in accordance with an embodiment of the invention;

FIG. 32 is a top view of the semiconductor device structure illustrated in FIG. 31;

FIG. 33 illustrates schematically, in cross-section, a semiconductor device structure that includes an inductor formed on a silicon portion and electrically connected to circuitry formed on a compound semiconductor portion;

FIG. 34 illustrates schematically, in cross-section, a semiconductor device structure that includes a multilayered inductor having a spiral portion formed on the structure's backside;

FIG. 35 is a bottom view of the device structure illustrated in FIG. 34;

FIG. 36 illustrates schematically, in cross-section, various alternative embodiments of the device structure illustrated in FIGS. 31 and 32 in which an inductor is formed in various layers of the device structure;

FIG. 37 illustrates schematically, in cross-section, a semiconductor device structure that includes a multilayered inductor with a ferromagnetic material between the coils in accordance with an embodiment of the invention;

FIG. 38 illustrates schematically a perspective front view of a semiconductor device structure that includes a multilayered Marchand balun in accordance with an embodiment of the invention;

FIG. 39 illustrates schematically a perspective side view of the semiconductor device structure illustrated in FIG. 38;

FIG. 40 illustrates schematically, in cross-section, a side view of the semiconductor device structure illustrated in FIGS. 38 and 39;

FIG. 41 illustrates schematically a perspective side view of a semiconductor device structure that includes a multilayered spiral balun in accordance with an embodiment of the invention;

FIG. 42 illustrates schematically a perspective top view of the semiconductor device structure illustrated in FIG. 41; and

FIG. 43 illustrates schematically a perspective front view a semiconductor device structure that includes another embodiment of a balun structure in accordance with an embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention. Additionally, for simplicity and clarity of illustration, the figures illustrate the general manner of construction, and descriptions and details of well-known features and techniques are omitted to avoid unnecessarily obscuring the invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, an accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

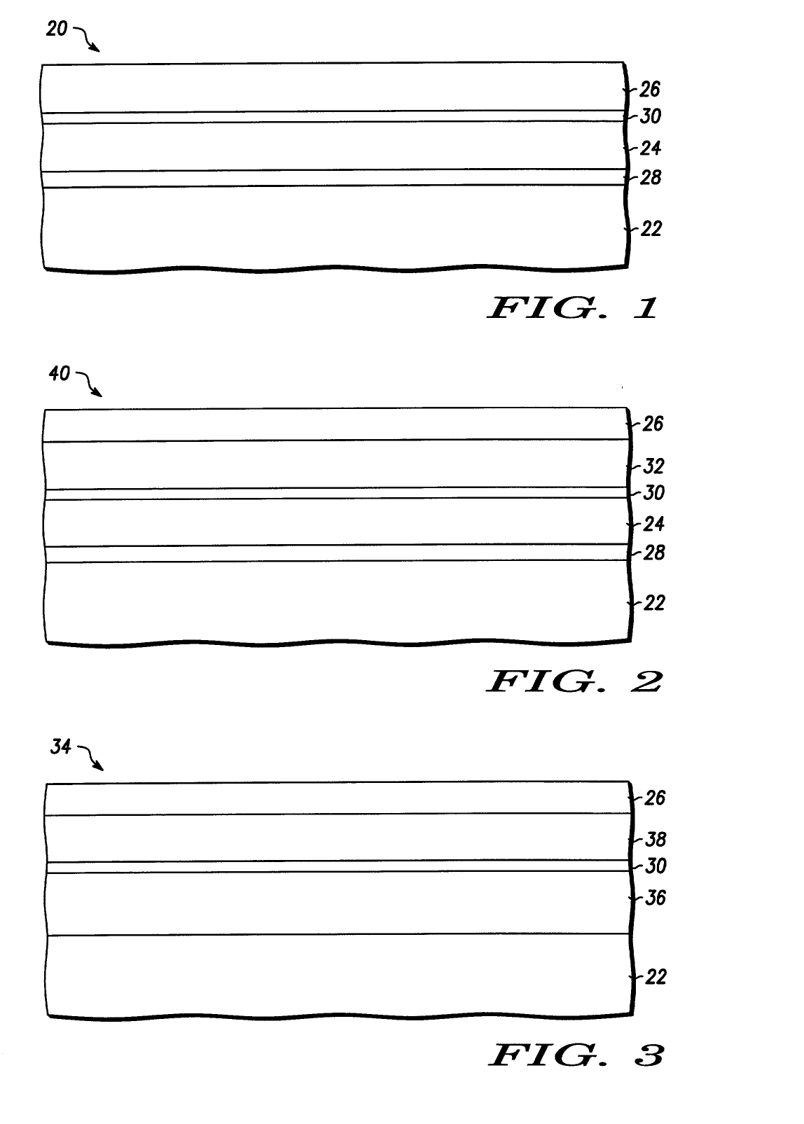

FIG. 2 illustrates, in cross section, a portion of a semiconductor structure 40 in accordance with a further embodiment of the invention. Structure 40 is similar to the previously described semiconductor structure 20, except that an additional buffer layer is 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer is thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O−P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5 -6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The is inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

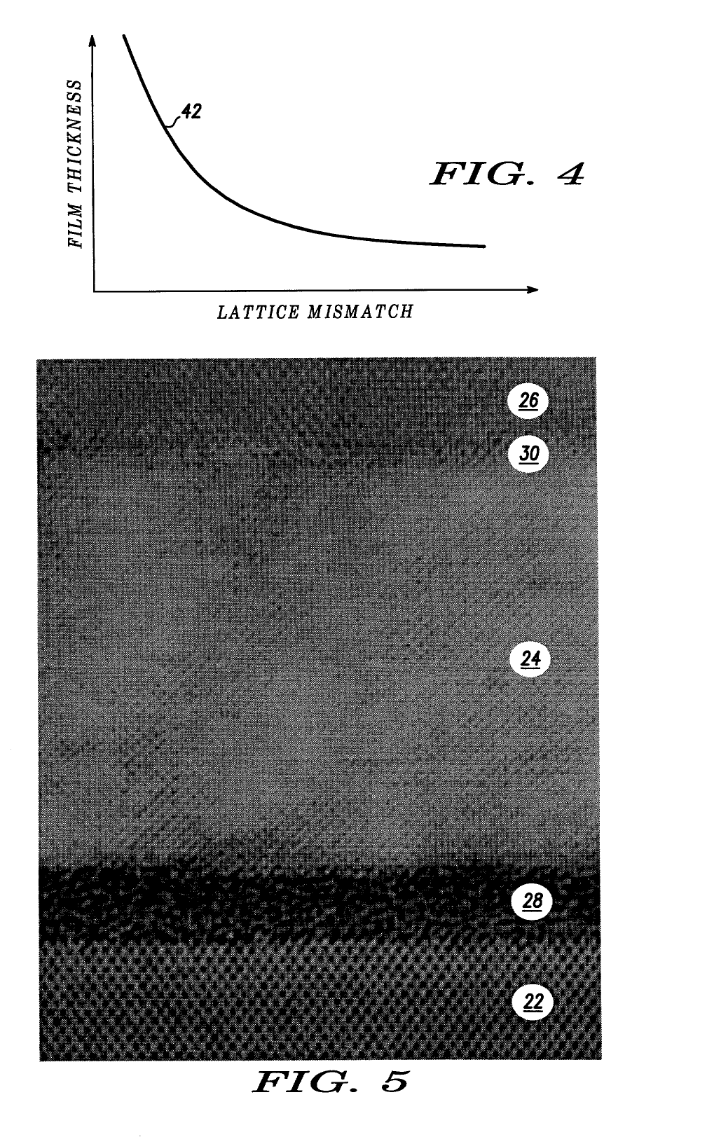

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

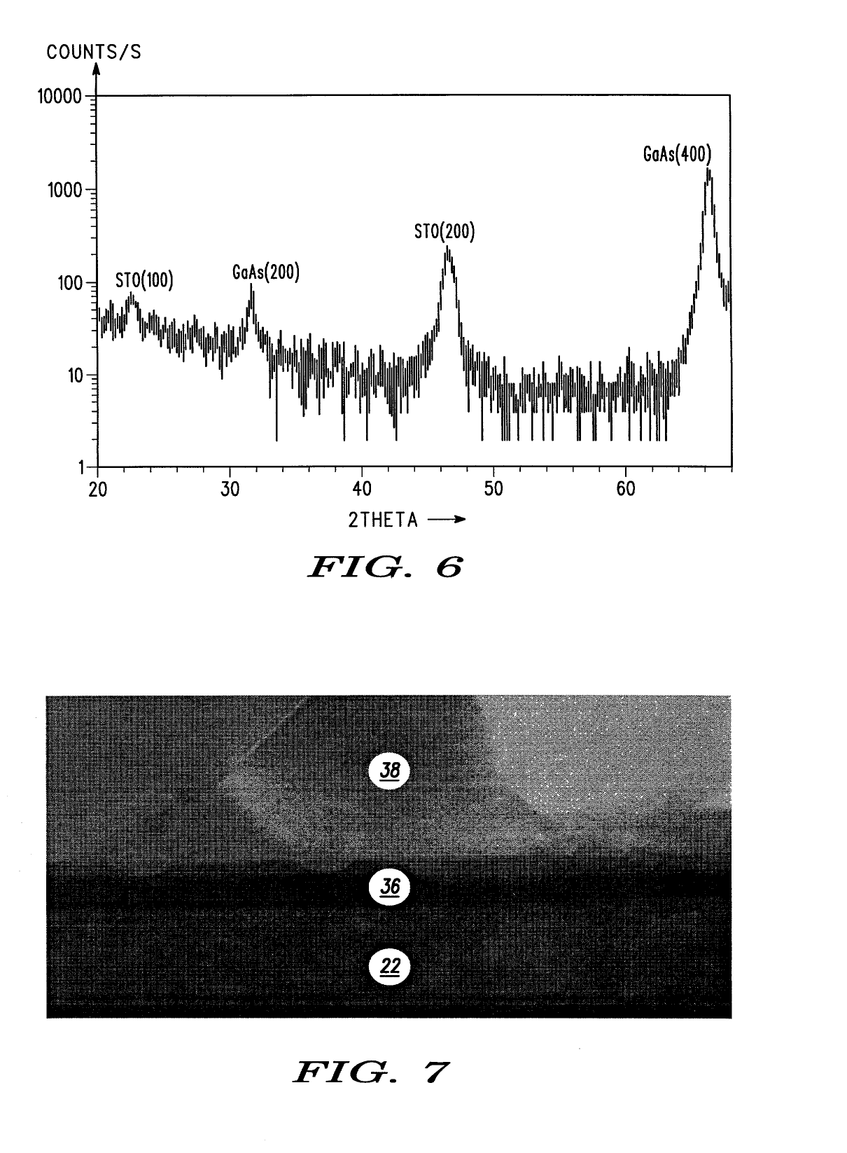

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above is with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

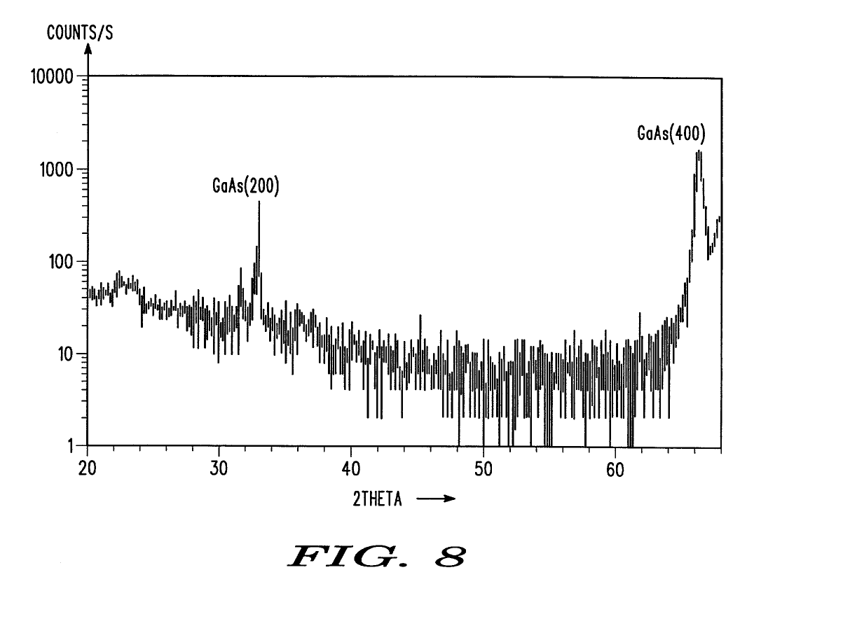

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating is buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

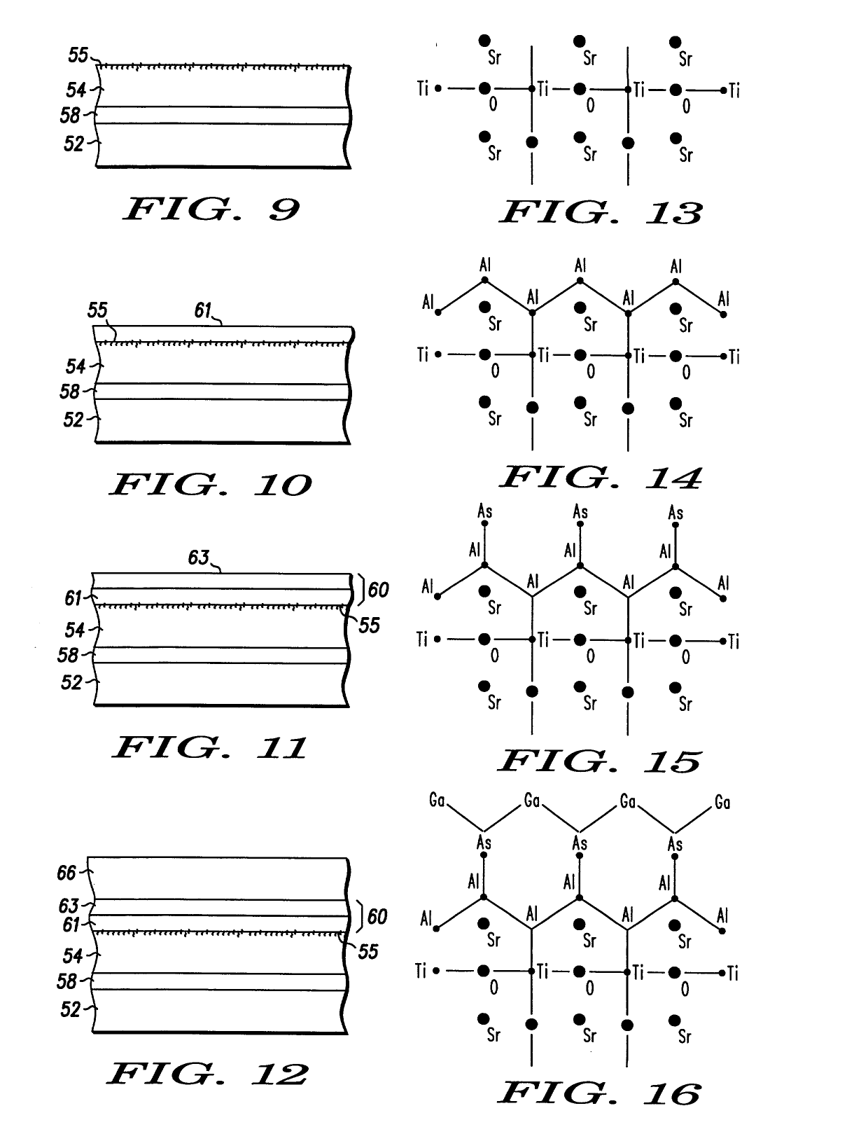

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

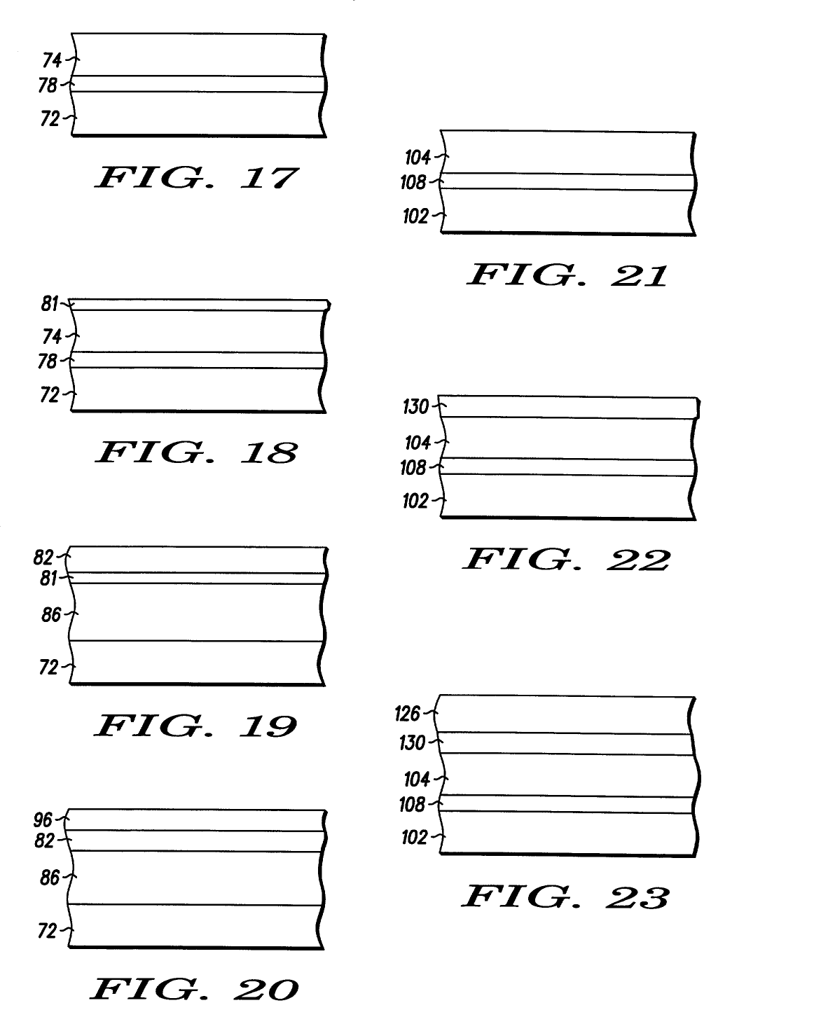

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

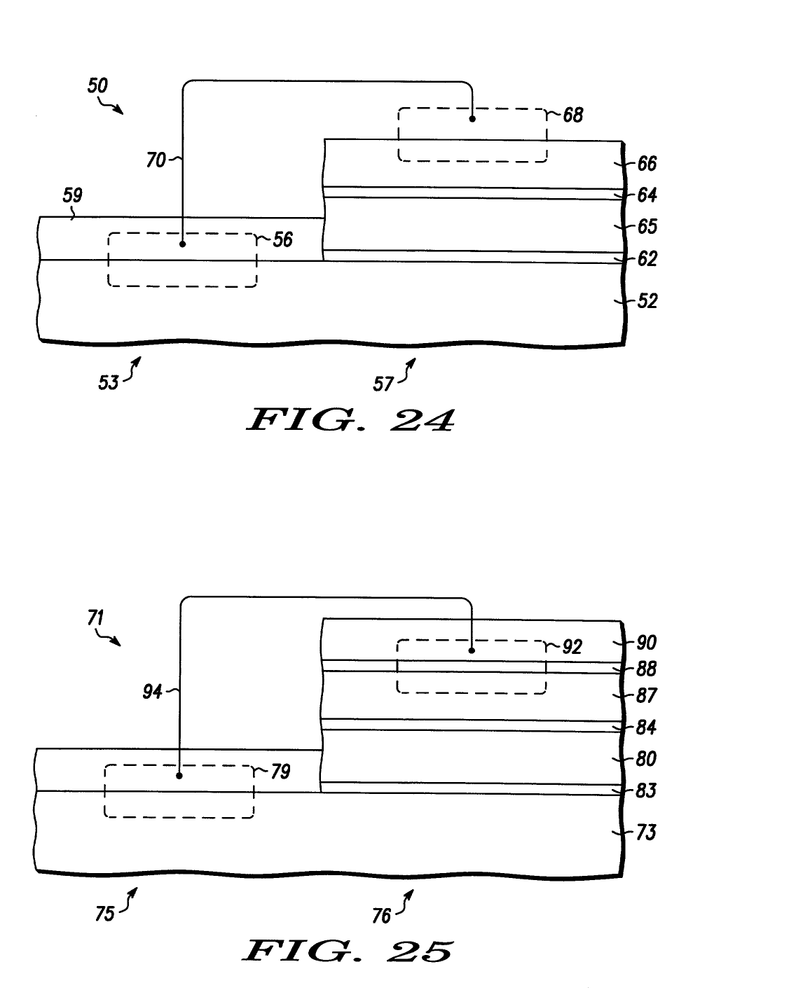

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64.

This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed, at least partially, in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed, at least partially, in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed, at least partially, in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

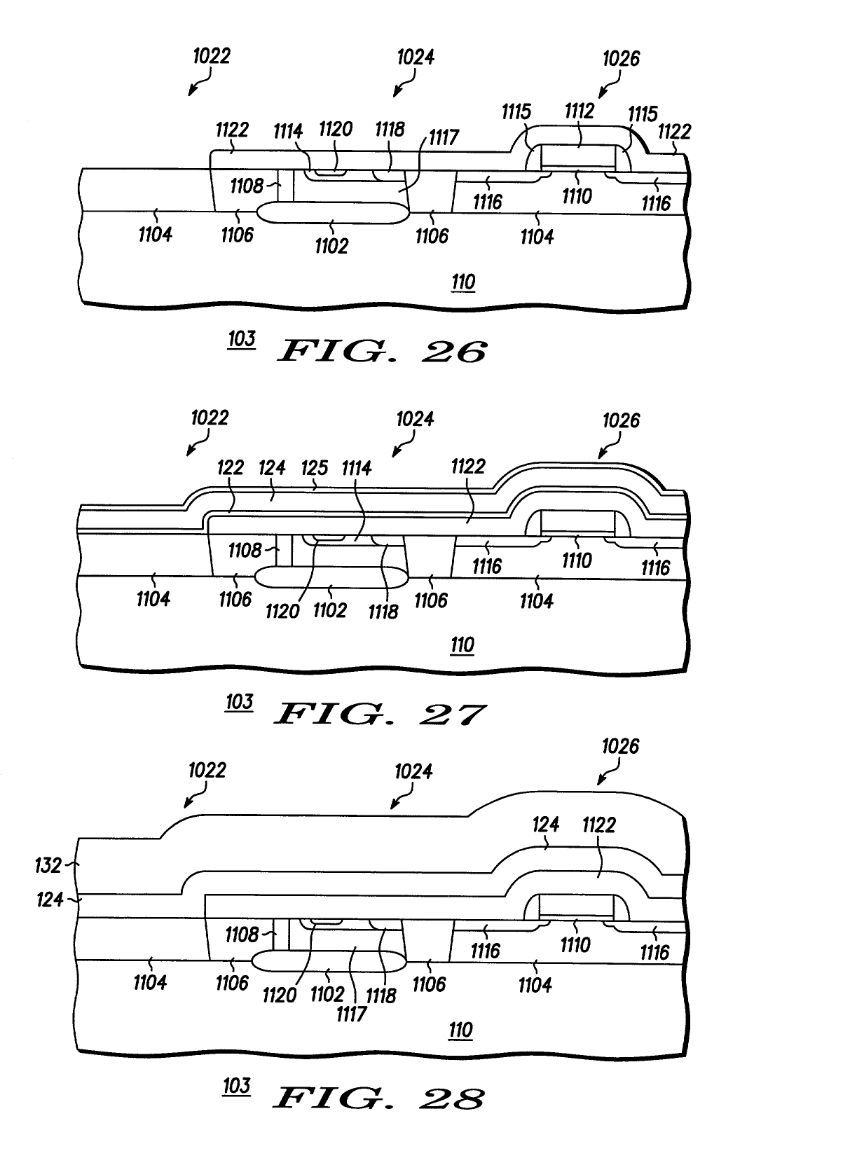

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110. A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

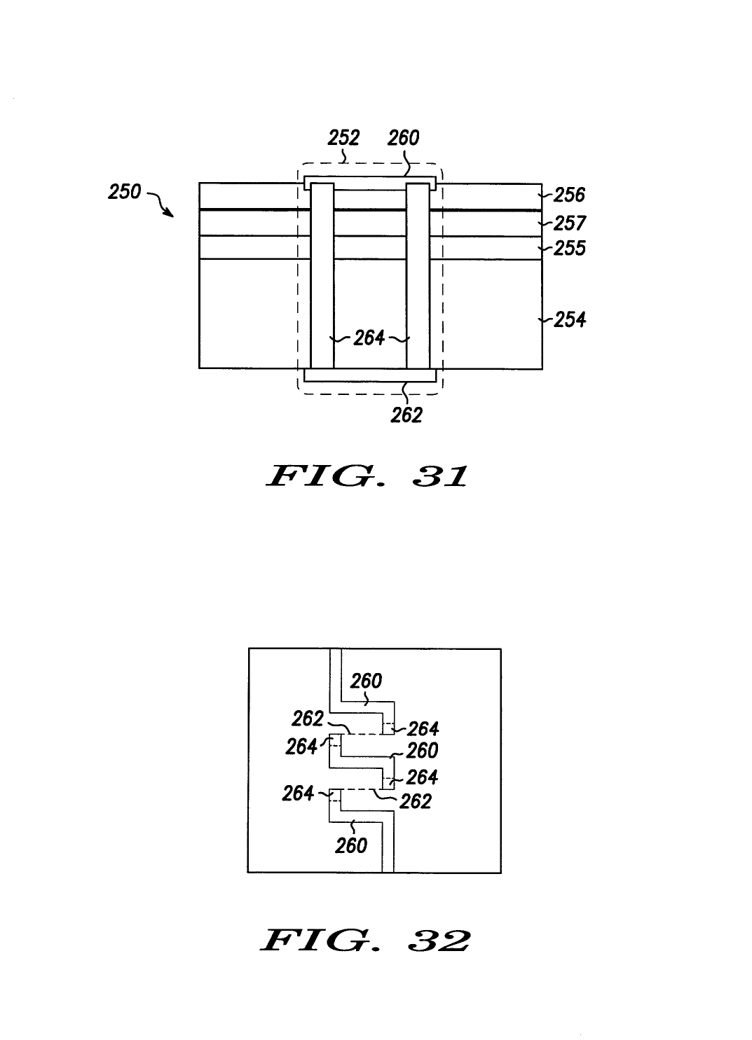

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

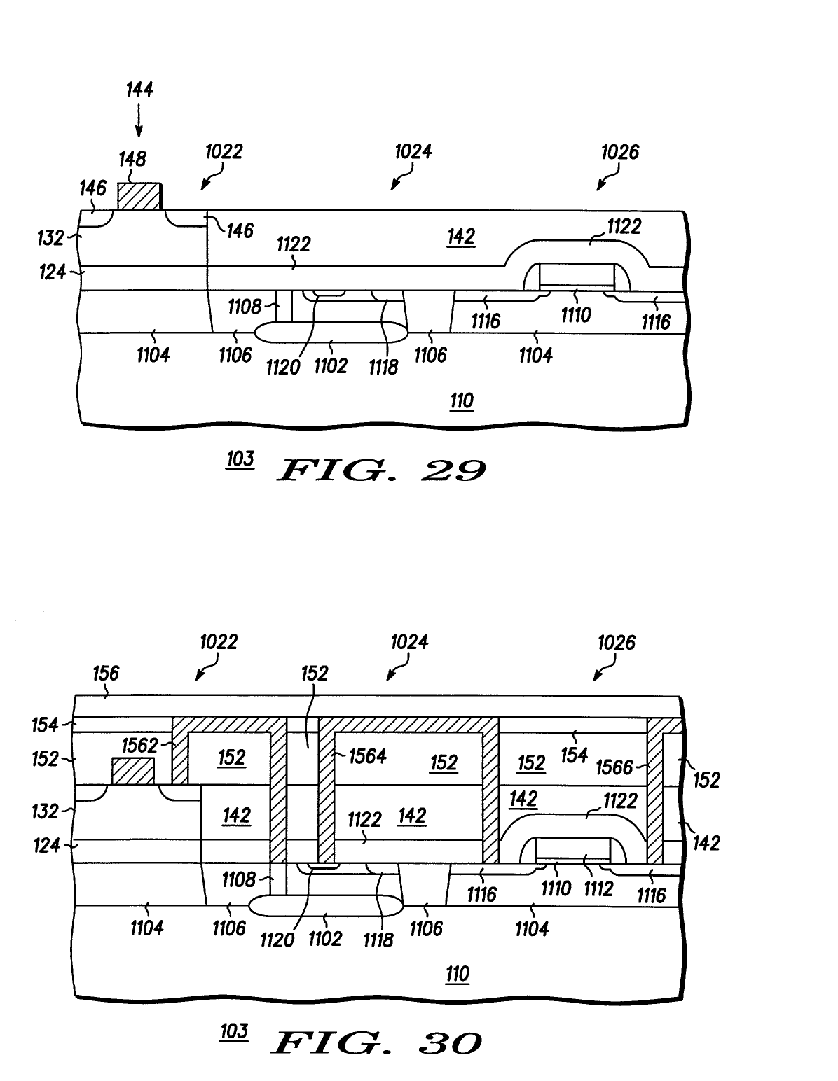

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

Attention is now directed to FIGS. 31-37, which illustrate various inductor structures in accordance with further embodiments of the invention. Among the advantages of the inductor structures disclosed herein is that occupy less die surface area than conventional structures.

FIGS. 31 and 32 illustrate an inductor generally indicated by dashed line 252 formed in and on multiple layers of a semiconductor device structure 250. Device structure 250 preferably includes a monocyrstalline silicon substrate 254, an amorphous oxide material 255 overlying the monocrystalline silicon substrate 254, an accommodating buffer layer 257 (e.g., a monocrystalline perovskite oxide material) overlying the amorphous oxide material 255, and a compound semiconductor material 256 overlying the accommodating buffer layer 257. With respect to FIGS. 31-37, other layers of the device structures are not shown so as not to obscure the presently discussed aspect of the invention.

Top traces 260 on compound semiconductor material 256 form the top of inductor 252. As used herein, the term “trace” refers broadly to any conductor, for example, a deposited metal or a doped conductive region. Top traces 260 preferably have an “S” shape or similar configuration to provide a coil-like structure for increased inductance, though no particular size or shape is required. Bottom traces 262 are formed on the structure's backside in or under the monocrystalline silicon substrate 254. Vias 264 extend vertically through the silicon substrate 254 and compound semiconductor material 256 layers, and electrically connect top traces 260 to bottom traces 262. Traces 260 and 262 and vias 264 can be formed of any of a number of conductive materials, preferably highly conductive metals such as gold, which are commonly used in the field of semiconductor fabrication. Traces 260 and 262 and vias 264 preferably form a coil-like structure that functions similar to a traditional spiral inductor formed by creating a coil in a single plane on the surface of a die. However, a coil-like configuration is not necessarily required and numerous other alternative configurations can be used.

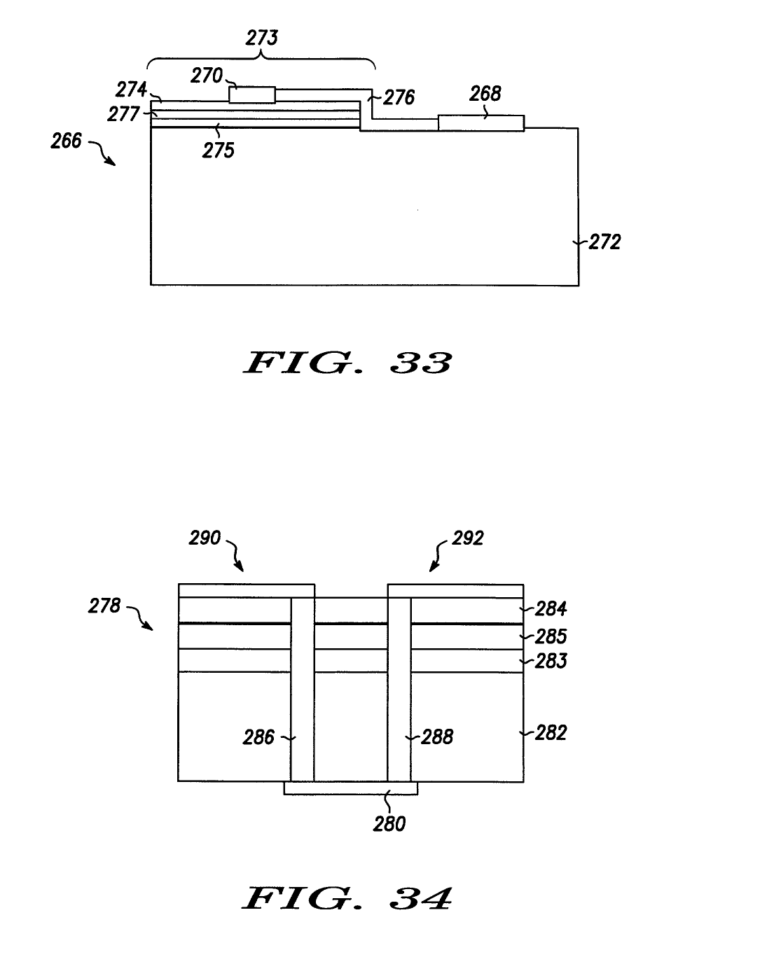

FIG. 33 illustrates a semiconductor device structure including an inductor 268 formed on a monocrystalline silicon substrate 272 and electrically connected to circuitry 270 on monocrystalline compound semiconductor material 274. Inductor 268 can be, for example, a traditional monolithic spiral inductor. Circuitry 270 is formed in a compound semiconductor portion 273 of device structure 266. Compound semiconductor portion 273 preferably includes a monocyrstalline silicon substrate 272, an amorphous oxide material 275 overlying the monocrystalline silicon substrate 272, an accommodating buffer layer 277 (e.g., a monocrystalline perovskite oxide material) overlying the amorphous oxide material 275, and a compound semiconductor material 274 overlying the accommodating buffer layer 277. Circuitry 270 can be any type of circuitry, for example a FET. Inductor 268 is electrically connected to circuitry 270 by interconnect 276, which can be a deposited metal such as gold. Inductor 268 can, alternatively, be formed on an epitaxial layer of silicon (not shown), so that the inductor 268 is at the same height as the circuitry 270. One benefit of forming the inductor 268 on the silicon substrate 272 is to provide increased loss. The amount of loss in the inductor can be controlled by changing the doping of the silicon substrate 272. Increased loss is often desired in various circuit designs, for example, for bias line isolation. Another advantage of forming the inductor on the silicon substrate 272 is to occupy less surface area on the compound semiconductor portion 274 of the device structure 266.

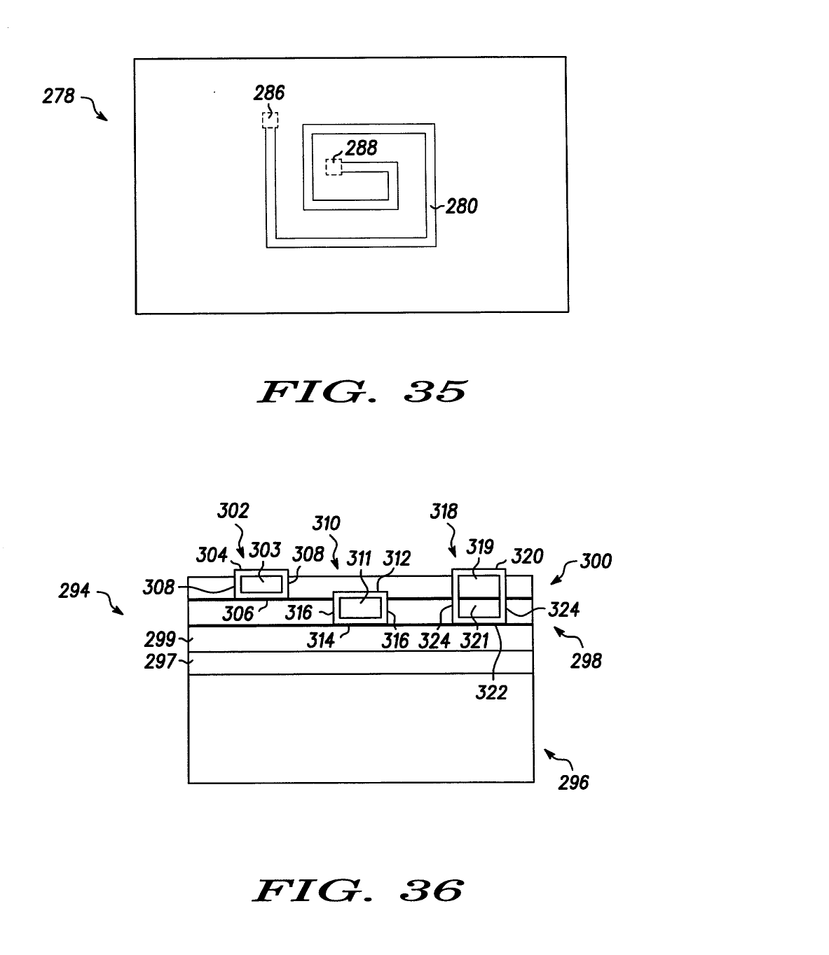

FIGS. 34 and 35 illustrate a monolithic spiral inductor formed on the backside of device structure 278. The device structure 278 preferably includes a monocyrstalline silicon substrate 282, an amorphous oxide material 283 overlying the monocrystalline silicon substrate 282, an accommodating buffer layer 285 (e.g., a monocrystalline perovskite oxide material) overlying the amorphous oxide material 283, and a compound semiconductor material 284 overlying the accommodating buffer layer 285. A spiral 280 of conductive material, for example, a highly-conductive metal, is formed on the backside of the device structure 278 under silicon substrate 282. The device structure 278 further includes device input 290 and device output 292, which preferably comprise a highly conductive metal such as gold deposited on compound semiconductor material 284. The spiral 280 is electrically connected to device input 290 and device output 292 by vias 286 and 288 formed through silicon substrate 282 and compound semiconductor 284. Among the advantages of this structure is that it significantly reduces the area on the active surface of the device structure occupied by the inductor.

FIG. 36 is a schematic side view illustrating examples of alternative embodiments of the device structure illustrated in FIGS. 31 and 32 in which the inductor is formed in various layers of the device structure. Device structure 294 preferably includes a monocyrstalline silicon substrate 296, an amorphous oxide material 297 overlying the monocrystalline silicon substrate 296, an accommodating buffer layer 299 (e.g., a monocrystalline perovskite oxide material) overlying the amorphous oxide material 297, and a compound semiconductor material 298 overlying the accommodating buffer layer 299. An additional material layer 300, which is not necessarily monocrystalline (e.g., a polyimide) can overly compound semiconductor layer 298.

Inductor 302 is formed as described with respect to FIGS. 31 and 32, except top traces 304 are formed on additional material layer 300. Bottom traces 306 are formed on compound semiconductor material 298 under additional material layer 300. Vias 308 extend vertically through additional material layer 300 and electrically connect bottom traces 306 and top traces 304. Inter-inductor material 303 overlying bottom trace 306 can comprise material forming additional material layer 300 or another material, which is not necessarily monocrystalline.

In another embodiment, inductor 310 is formed in compound semiconductor layer 298. Top traces 312 are formed on compound semiconductor material 298. Bottom traces 314 are formed on silicon substrate 296. Vias 316 are formed through compound semiconductor layer 298 and electrically connect bottom traces 314 and top traces 312. Inter-inductor material 311 overlying bottom trace 314 can comprise material forming monocrystalline compound semiconductor material 298 or another material, which is not necessarily monocrystalline.

Another embodiment is illustrated by inductor 318, which is formed through compound semiconductor material layer 298 and additional material layer 300. Top traces 320 are formed on additional material layer 300. Bottom traces 322 are formed on silicon substrate 296. Vias 324 are formed through compound semiconductor material 298 and additional material 300 and electrically connect bottom traces 322 and top traces 320. Inter-inductor materials 319 and 321 overlying bottom trace 322 can comprise material forming monocrystalline compound semiconductor material 298 and additional material layer 300, or other material or materials, which are not necessarily monocrystalline.

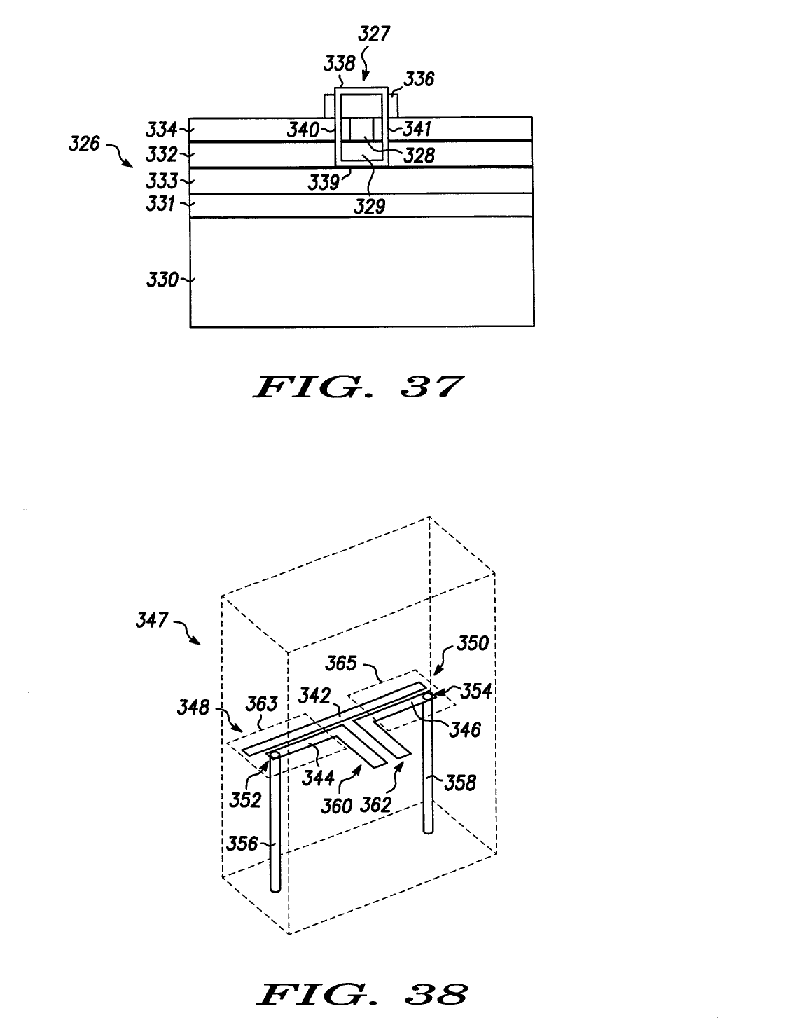

FIG. 37 illustrates an example of a semiconductor device structure 326 having a multilayered inductor 327 that includes a ferromagnetic material 328 between the inductor coils to increase inductance. Device structure 326 preferably includes a monocyrstalline silicon substrate 330, an amorphous oxide material 331 overlying the monocrystalline silicon substrate 330, an accommodating buffer layer 333 (e.g., a monocrystalline perovskite oxide material) overlying the amorphous oxide material 331, and a compound semiconductor material 332 overlying the accommodating buffer layer 333. Two additional material layers 334 and 336 overly compound semiconductor layer 332. Additional material layers 334 and 336 can comprise deposited dielectric materials (e.g., a polyimide material). Additional material layers 334 and 336 can alternatively comprise one layer of material. Material 329 overlying trace 340 can comprise compound semiconductor material 332 and/or material forming additional material layers 334 and 336 or another material, which is not necessarily monocrystalline (e.g., a deposited dielectric material such as polyimide). Inductor 327 includes top traces 338 formed on additional material layer 336. Bottom traces 339 are formed on silicon substrate 330. Vias 340 and 341 electrically connect bottom traces 339 and top traces 338. At least a portion of additional material layer 334 between vias 340 and 341 comprises a ferromagnetic material 328. This structure effectively places a ferromagnetic material within the coils of the inductor, which increases inductance.

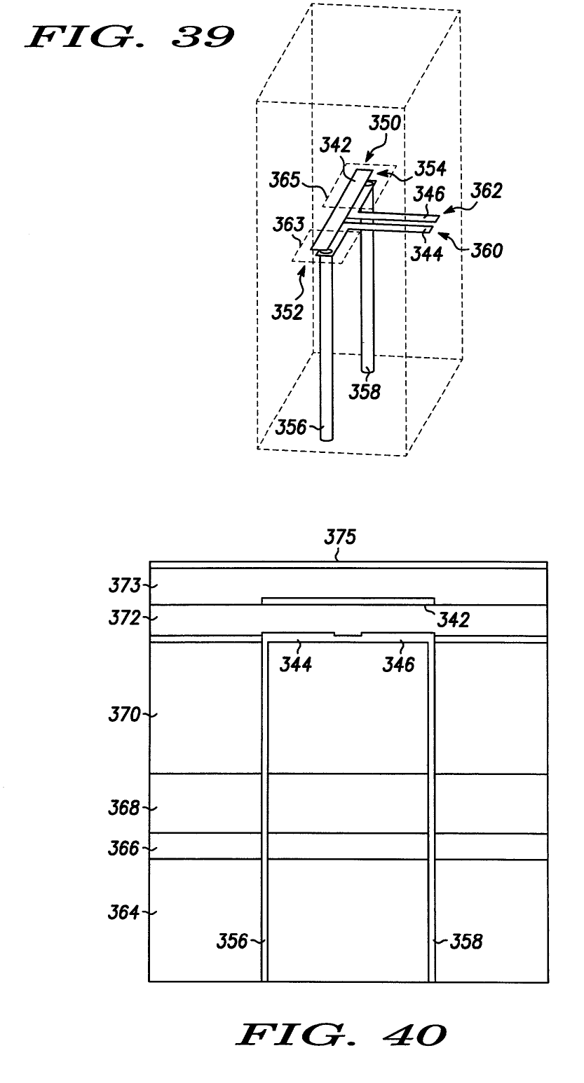

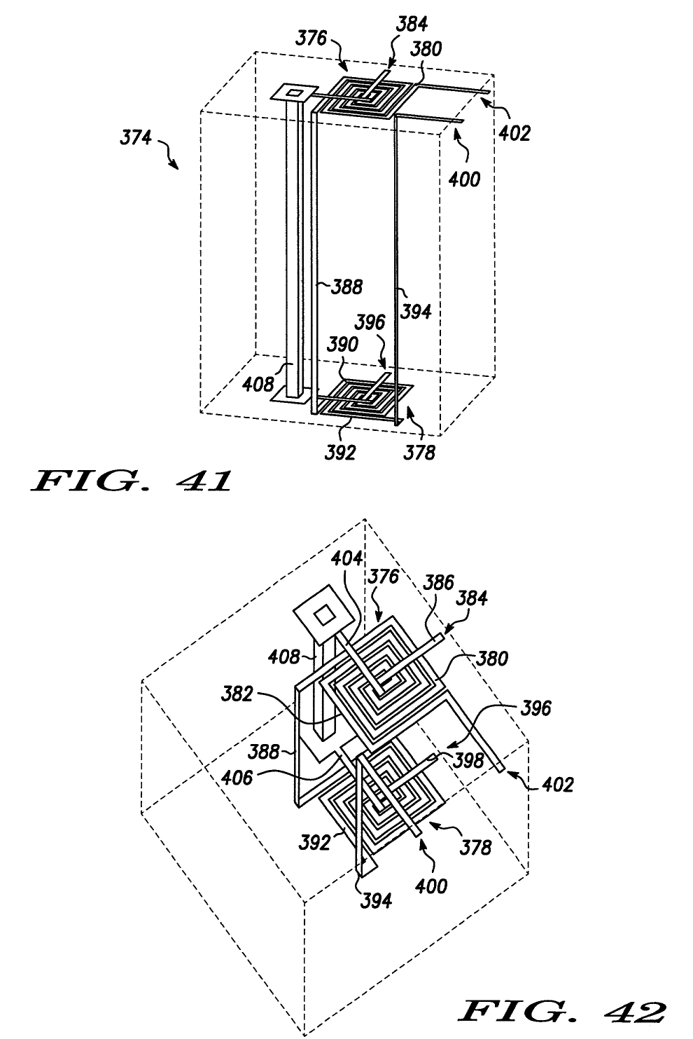

Attention is now directed to FIGS. 38-43, which illustrate various multilayered balun structures in accordance with further embodiments of the invention. One of the advantages of these structures is that they occupy less surface area on the die.

FIGS. 38, 39 and 40 illustrate device structure 347, which includes a multilayered Marchand balun in accordance with an embodiment of the invention. As shown in FIG. 40, device structure 347 has a plurality of layers. Device structure 347 preferably includes a monocyrstalline silicon substrate 364, an amorphous oxide material 366 overlying the monocrystalline silicon substrate 364, an accommodating buffer layer 368 (e.g., a monocrystalline perovskite oxide material) overlying the amorphous oxide material 366, a compound semiconductor material 370 overlying the accommodating buffer layer 368, and a dielectric material 372 overlying the compound semiconductor layer 370. The layers of the device structure are not shown in FIGS. 38 and 39 and 41, 42 and 43 so as not to obscure the presently discussed aspect of the invention. For example, as discussed above with reference to FIGS. 1-24, the device structures can include the material layers 364, 366, 368, 370 and 372, shown in FIG. 40, and other materials such as deposited metals and dielectric materials.

Referring again to FIGS. 38, 39 and 40, the balun includes three transmission lines 342, 344 and 346, which are a formed of a conductive material, preferably a deposited metal. Transmission line 342 has an input terminal 348 at one end to which an unbalanced input signal is applied. At the other end, transmission line 342 has an open terminal 350. As used herein, the term “open” refers broadly to an open circuit and the functional equivalent to an open circuit, for example a terminal that is electrically connected to a large resistor. Transmission lines 344 and 346 include ground terminals 352 and 354 at one end, which are grounded by vias 356 and 358, which extend through underling layers 364, 366, 368 and 370. Output terminals 360 and 362 at the other end of transmission lines 344 and 346 provide output signals that are substantially equal in amplitude and approximately 180 degrees out of phase with each other at a desired frequency. The balun is realized by two coupled line sections generally indicated by dashed lines 363 and 365 whose electrical length is preferably approximately 90 degrees at the frequency of interest. As used herein, the term “coupled” refers broadly to placing two unshielded transmission lines in close proximity, such that RF power can be transmitted between the lines due to the interaction of the electromagnetic fields of each line, or the functional equivalent thereof. Coupled transmission lines often consist of three (two lines plus the ground plane) conductors close together, although more conductors can be used. In one coupled line section 363 the terminal connected to ground 352 is adjacent to input terminal 348. The ground terminal 354 on the other coupled line section 365 is adjacent to open terminal 350. The two output terminals 360 and 362 are physically connected with ground terminals 352 and 354, but preferably at an electrical length of approximately 90 degrees at the frequency of interest.

As shown in FIG. 40, transmission line 342 is formed in a different layer than transmission lines 344 and 346, such that transmission line 342 is offset vertically from transmission lines 344 and 346. In the example shown, transmission line 342 is formed on dielectric material layer 372 and transmission lines 344 and 346 are formed on underlying compound semiconductor layer 370. Transmission line 342 is coupled with transmission line 344 and 346 through dielectric layer 372. The transmission lines are broadside coupled by vertical stacking of the transmission lines 342, 344 and 346 in multiple layers of the device structure 347 (as opposed to traditional edge coupling through a side-by-side arrangement in a horizontal plane on a single layer). The thickness of the layers between transmission line 342 and transmission lines 344 and 346 depends upon the frequency, application requirements, and manufacturing consideration. The thickness of the dielectric material between the transmission lines effects the amount of coupling achieved. In this example the transmission lines 342, 344 and 346 of the balun structure are formed on dielectric layer 372 and compound semiconductor layer 370. Alternatively, the transmission line 342 and/or transmission lines 344 and 346 can be formed on other layers, for example the transmission lines can also be formed on silicon substrate material 364. Various other layer configurations are also possible. Optionally, a ground plane 375 comprising a conductive layer (e.g., a deposited metal) can overly the upper transmission line 342 with an additional dielectric material layer 373 formed between the upper transmission line 342 and the ground plane 375.

FIG. 41 illustrates a semiconductor device structure 374 that includes a multilayered spiral balun in accordance with an embodiment of the invention. The device structure 374 preferably includes a plurality of layers, which, as discussed above, are not shown so as not to obscure the presently discussed aspect of the invention.

Spiral balun structures are another use of monolithic spiral inductors discussed above. In the spiral balun structure, the coupled line sections are wound in a spiral to reduce surface area on the die occupied by the device. The spiral balun structure includes an upper spiral 376 and a lower spiral 378, which are formed on separate layers of device structure 374 to reduce the surface area occupied by the device. Spirals 376 and 378 are separated by one or more dielectric layers (not shown). Spiral 376 comprises two sets of coupled transmission lines 380 and 382, which form concentric spirals wound in opposite directions. In the example shown, spirals 376 and 378 are square. The spirals 376 and 378 can also be various other shapes (e.g., rectangular, circular, etc.). The dimensions of the spirals is determined by the application requirements (e.g., frequency of the application). Transmission line 382 is electrically connected to ground via 408 at one end. At the other end, transmission line 382 comprises output terminal 402. The input signal is applied at input terminal 384. The signal is electrically connected to transmission line 380 at the center of spiral 376 by air bridge 386. Transmission line 380 reaches the outer perimeter of spiral 376 and electrically connects through via 388 to transmission line 390 on the outer perimeter of lower spiral 378, which is composed of two coupled transmission lines 390 and 392, which form concentric spirals wound in opposite directions. Transmission line 392 is electrically connected to ground via 408 at one end. At the other end, transmission line 392 is electrically connected to output terminal 400 through via 394. The input signal is physically connected through air bridge 398 to open terminal 396. The output signals at output terminals 400 and 402 are substantially equal in amplitude and approximately 180 degrees apart at a desired frequency. The two output terminals 400 and 402 are physically connected to grounded terminals by air bridges 404 and 406 connected to ground via 408, at an electrical length of approximately 90 degrees at the desired frequency. Alternatively, air bridges 404 and 406 can have separate ground connections.

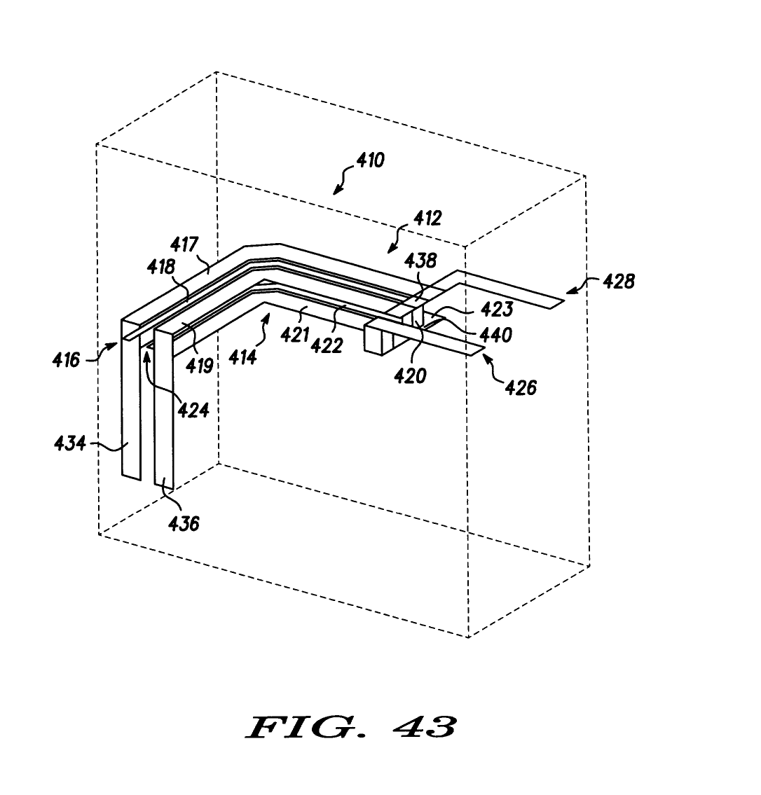

FIG. 43 illustrates a semiconductor device structure that includes another embodiment of a balun structure in accordance with the invention. The device structure 410 preferably includes a plurality of layers, which, as discussed above, are not shown so as not to obscure the presently discussed aspect of the invention. The balun comprises two sets of three coupled transmission lines 412 and 414 separated by one or more dielectric layers (not shown). Upper line set 412 comprise outer transmission lines 417 and 419 and center transmission line 418. Lower line set 414 comprises outer transmission lines 421 and 423 and center transmission line 422. Each set of lines 412 and 414 has an electrical length of approximately 90 degrees at the frequency of interest. Upper line set 412 and lower line set 414 are on different layers of device structure 410 to minimize layout area required by the device. The example shown illustrates the line sets 412 and 414 in a “L” shape, but other shapes such as a “U” shape and straight-line configuration can also be used. The input signal is applied at input terminal 416. The signal is transmitted through center transmission line 418 of upper line set 412. The signal connects to center transmission line 422 of lower line set 414 through via 420 to an open terminal 424. Thus, the input signal is physically connected to open terminal 424 through via 420. The structure includes output terminals 426 and 428. The output signals at output terminals 426 and 428 are substantially equal in amplitude and approximately 180 degrees apart at the frequency of interest. The two output terminals 426 and 428 are physically connected to ground by ground vias 434 and 436 and air bridges 438 and 440, but at an electrical length of approximately 90 degrees at the desired frequency.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a plurality of layers comprising:
a monocrystalline silicon substrate;
an amorphous oxide material overlying the monocrystalline silicon substrate;
a monocrystalline perovskite oxide material overlying the amorphous oxide material; and
a monocrystalline compound semiconductor material overlying the monocrystalline perovskite oxide material; and
an inductor comprising:
a top conductor formed in or over a first of the plurality of layers;
a bottom conductor formed in or over a second of the plurality of layers; and
at least one via electrically connecting the top conductor to the bottom conductor.

2. The semiconductor structure of claim 1, wherein in the top conductor comprises a plurality of traces in or over the monocrystalline compound semiconductor material.

3. The semiconductor structure of claim 1, wherein the bottom conductor comprises a plurality of traces in or over the monocrystalline silicon substrate.

4. The semiconductor structure of claim 1, wherein the at least one via comprises a plurality of vias extending vertically through the monocrystalline silicon substrate, amorphous oxide material, monocrystalline perovskite oxide material, and monocrystalline compound semiconductor material.

5. A semiconductor structure comprising:
a plurality of layers comprising:
a monocrystalline silicon substrate;
an amorphous oxide material overlying the monocrystalline silicon substrate;
a monocrystalline perovskite oxide material overlying the amorphous oxide material; and
a monocrystalline compound semiconductor material overlying the monocrystalline perovskite oxide material; and
an inductor comprising:
a top conductor formed in or over a first of the plurality of layers;
a bottom conductor formed in or under a second of the plurality of layers; and
at least one via electrically connecting the top conductor to the bottom conductor.

6. The semiconductor structure of claim 5, wherein in the top conductor comprises a plurality of traces in or over the monocrystalline compound semiconductor material.

7. The semiconductor structure of claim 5, wherein the semiconductor structure comprise a backside and the bottom conductor comprises a plurality of traces on the backside in or under the monocrystalline silicon substrate.

8. The semiconductor structure of claim 5, wherein the at least one via comprises a plurality of vias extending vertically through the monocrystalline silicon substrate, amorphous oxide material, monocrystalline perovskite oxide material, and monocrystalline compound semiconductor material.

9. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
an inductor comprising:
a top conductor in or over the monocrystalline compound semiconductor material;
a bottom conductor in or under the monocrystalline silicon substrate; and
at least one via electrically connecting the top conductor to the bottom conductor.

10. The semiconductor structure of claim 9, wherein in the top conductor comprises a plurality of traces in or over the monocrystalline compound semiconductor material.

11. The semiconductor structure of claim 9, wherein the semiconductor structure comprise a backside and the bottom conductor comprises a plurality of traces on the backside in or under the monocrystalline silicon substrate.

12. The semiconductor structure of claim 9, wherein the at least one via comprises a plurality of vias extending vertically through the monocrystalline silicon substrate, amorphous oxide material, monocrystalline perovskite oxide material, and monocrystalline compound semiconductor material.

13. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
an inductor formed in or over the monocrystalline silicon substrate; and
circuitry formed in or over the compound semiconductor material and electrically connected to the inductor.

14. The semiconductor structure of claim 13, wherein the circuitry comprises a device formed in or over the compound semiconductor material.

15. The semiconductor structure of claim 13, wherein the inductor comprises a monolithic spiral inductor.

16. The semiconductor structure of claim 13, wherein the structure comprises:
a silicon portion comprising a monocrystalline silicon substrate, and
a compound semiconductor portion comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
an inductor formed in the silicon portion; and
circuitry formed in the compound semiconductor portion and electrically connected to the inductor.

17. A semiconductor structure having a topside and a backside, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
an inductor formed on the backside;
an inductor input and output formed on the topside; and
two vias electrically connecting the inductor formed on backside to the inductor input and output formed on the top side.

18. The semiconductor structure of claim 17, wherein the inductor comprises a monolithic spiral inductor.

19. The semiconductor structure of claim 17, wherein the at least two vias extend vertically through the monocrystalline silicon substrate, amorphous oxide material, monocrystalline perovskite oxide material, and monocrystalline compound semiconductor material.

20. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a dielectric material overlying the monocrystalline compound semiconductor material; and
an inductor comprising:
a top conductor in or over the dielectric material;
a bottom conductor in or over the monocrystalline compound semiconductor material; and
at least one via electrically connecting the top conductor to the bottom conductor.

21. The semiconductor structure of claim 20, wherein in the top conductor comprises a plurality of traces in or over the dielectric material.

22. The semiconductor structure of claim 20, wherein the bottom conductor comprises a plurality of traces in or over the monocrystalline compound semiconductor material.

23. The semiconductor structure of claim 20, wherein the at least one via comprises two vias extending vertically through the monocrystalline silicon substrate, amorphous oxide material, monocrystalline perovskite oxide material, and monocrystalline compound semiconductor material.

24. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
an inductor comprising:
a top conductor in or over the monocrystalline compound semiconductor material;
a bottom conductor in or over the monocrystalline silicon substrate; and
at least one via electrically connecting the top conductor to the bottom conductor.

25. The semiconductor structure of claim 24, wherein in the top conductor comprises a plurality of traces in or over the monocrystalline compound semiconductor material.

26. The semiconductor structure of claim 24, wherein the bottom conductor comprises a plurality of traces in or over the monocrystalline silicon substrate.

27. The semiconductor structure of claim 24, wherein the at least one via comprises two vias extending vertically through the monocrystalline compound semiconductor material.

28. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a dielectric material overlying the monocrystalline compound semiconductor material; and
an inductor comprising:
a top conductor in or over the dielectric material;
a bottom conductor in or over the monocrystalline silicon substrate; and
at least one via electrically connecting the top conductor to the bottom conductor.

29. The semiconductor structure of claim 28, wherein in the top conductor comprises a plurality of traces in or over the dielectric material.

30. The semiconductor structure of claim 28, wherein the bottom conductor comprises a plurality of traces in or over the monocrystalline silicon substrate.

31. The semiconductor structure of claim 28, wherein the at least one via comprises two vias extending vertically through the amorphous oxide material, monocrystalline perovskite oxide material, monocrystalline compound semiconductor material, and dielectric material.

32. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
at least one dielectric material layer overlying the monocrystalline compound semiconductor material; and
an inductor comprising:
a top conductor in or over the dielectric material;
a bottom conductor in or over the monocrystalline silicon substrate;
at least two vias electrically connecting the top conductor to the bottom conductor; and
a ferromagnetic material between the at least two vias.

33. The semiconductor structure of claim 32, wherein in the top conductor comprises a plurality of traces in or over the at least one dielectric material layer.

34. The semiconductor structure of claim 32, wherein the bottom conductor comprises a plurality of traces in or over the monocrystalline silicon substrate.

35. The semiconductor structure of claim 32, wherein the at least two vias comprise vias extending vertically through the amorphous oxide material, monocrystalline perovskite oxide material, monocrystalline compound semiconductor material, and at least one dielectric material layer.

36. The semiconductor structure of claim 32, wherein the at least one dielectric layer comprises a lower and an upper dielectric material layer, and wherein the top conductor is formed in or over the upper dielectric material layer.

37. The semiconductor structure of claim 36, wherein the ferromagnetic material is formed in the lower dielectric material layer and the upper dielectric material layer is formed over the lower dielectric material layer and the ferromagnetic material.

38. A semiconductor structure comprising:
a plurality of layers comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a balun comprising:
a first transmission line comprising a first end comprising an input terminal and a second end comprising an open terminal, wherein the first transmission line is formed in or over a first of the plurality of layers;
a second transmission line comprising a first end comprising a ground terminal and a second end comprising an output terminal, wherein the second transmission line is formed in or over a second of the plurality of layers and is coupled with the first transmission line; and
a third transmission line comprising a first end comprising a ground terminal and a second end comprising an output terminal; wherein the third transmission line is formed in or over the second of the plurality of layers and is coupled with the first transmission line.

39. The semiconductor structure of claim 38, wherein the second and third transmission lines are substantially parallel to the first transmission line, and wherein the ground terminal of the second transmission line is adjacent to the input terminal of the first transmission line, and the ground terminal of the third transmission line is adjacent to the open terminal of the first transmission line.

40. The semiconductor structure of claim 38, further comprising two vias electrically connecting the ground terminals to ground.

41. The semiconductor structure of claim 38, wherein the balun is a Marchand balun.

42. The semiconductor structure of the claim 38, wherein the first transmission line is formed in or over the monocrystalline compound semiconductor material and the second and third transmission lines are formed in or over the monocrystalline silicon substrate.

43. The semiconductor structure of claim 38, further comprising a dielectric material layer overlying the first, second and third transmission lines and a ground plane overlying the dielectric material layer.

44. A semiconductor structure comprising:
a plurality of layers comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a balun comprising:
an upper spiral structure formed in or over a first of the plurality of layers comprising:
a first transmission line wound in a spiral, wherein the first transmission line comprises a first end comprising an input terminal and a second end electrically connected to a via; and
a second transmission line wound in a spiral and coupled with the first transmission line, wherein the second transmission line comprises a first end comprising a ground terminal and a second end comprising an output terminal; and
a lower spiral structure formed in or over a second of the plurality of layers comprising:
a third transmission line wound in a spiral, wherein the third transmission line comprises a first end electrically connected to the via and a second end comprising an open terminal; and
a fourth transmission line wound in a spiral and coupled with the third transmission line, wherein the fourth transmission line comprises a first end comprising a ground terminal and a second end electrically connected to an output terminal.

45. The semiconductor structure of claim 44, wherein the first and second transmission lines form concentric spirals wound in opposite directions, and wherein the third and forth transmission lines form concentric spirals wound in opposite directions.

46. The semiconductor structure of claim 44, further comprising a ground via electrically connecting the ground terminals of the second and fourth transmission lines to ground.

47. The semiconductor structure of claim 44, wherein the upper spiral structure is formed in or over the monocrystalline compound semiconductor material and the lower spiral structure is formed in or over the monocrystalline silicon substrate.

48. The semiconductor structure of claim 44, further comprising a via electrically connecting the fourth transmission line to an output terminal in or over the first of the plurality of layers.

49. A semiconductor structure comprising:
a plurality of layers comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a balun comprising:
an upper line structure formed in or over a first of the plurality of layers, wherein the upper line structure comprises:
a first and second outer transmission line each comprising a first end electrically connected to ground and a second end electrically connected to an output terminal;
an upper center transmission line between the first and second transmission lines comprising a first end comprising an input terminal and a second end electrically connected to a via; and
a lower line structure formed in or over a second of the plurality of layers, wherein the lower line structure comprises:
a third and fourth outer transmission lines each comprising a first end electrically connected to ground and a second end electrically connected to an output terminal; and
a lower center transmission line between the third and fourth outer transmission lines comprising a first end electrically connected to the via and a second end comprising an open terminal.

50. The semiconductor structure of claim 49, further comprising two ground vias electrically connecting the outer transmission lines to ground.

51. The semiconductor structure of claim 49, wherein the upper line structure is formed in or over the monocrystalline compound semiconductor material and the lower line structure is formed in or over the monocrystalline silicon substrate.
